(19) United States
(12) Patent Application Publication
(10) Pub. No.: US 2026/0258551 A1
(43) Pub. Date: Sep. 3, 2026

(54) MOLYBDENUM COMPOUND, METHOD FOR PREPARING SAME, AND METHOD FOR MANUFACTURING THIN FILM COMPRISING SAME

(71) Applicant: DNF CO., LTD., Daedeok-gu, Daejeon (KR)

(72) Inventors: Yonghee KWONE, Daedeok-gu, Daejeon (KR); Youngjae IM, Daedeok-gu, Daejeon (KR); Sangyong JEON, Daedeok-gu, Daejeon (KR); Taeseok BYUN, Daedeok-gu, Daejeon (KR); Sangchan LEE, Daedeok-gu, Daejeon (KR); Sangick LEE, Daedeok-gu, Daejeon (KR)

(21) Appl. No.: 18/718,364

(22) PCT Filed: Dec. 1, 2022
(86) PCT No.: PCT/KR2022/019325

§ 371 Date: Jun. 10, 2024

(30) Foreign Application Priority Data
Dec. 13, 2021 (KR) 10-2021-0177724

(51) Int. Cl. C23C 16/455; C07F 11/00; C23C 16/18

(52) U.S. Cl. CPC C23C 16/45553; C07F 11/00; C23C 16/18

(57) ABSTRACT

The present invention relates to: a molybdenum compound; a method for preparing same; a molybdenum-containing thin film deposition composition comprising same; and a method for manufacturing a molybdenum-containing thin film using same. The molybdenum compound of the present invention has excellent thermal stability, high volatility, and enhanced vapor pressure, and thus may be employed to manufacture a molybdenum-containing thin film having a uniform thickness at an enhanced deposition rate.

### TECHNICAL FIELD

The present invention relates to a molybdenum compound, a preparation method of the same, a manufacturing method of a thin film containing the same, and a thin film containing the same.

### BACKGROUND ART

Various organometallic precursors are used to form metal thin films. Various techniques have been used for deposition of the thin films, and examples thereof include a reactive sputtering method, an ion-assisted deposition method, a sol-gel deposition method, a metal organic chemical vapor deposition (MOCVD) method, which is a type of a chemical vapor deposition (CVD) method, and an atomic layer deposition (ALD) method, which is also called atomic layer epitaxy (ALE). The chemical vapor deposition (CVD) method and the atomic layer deposition (ALD) method have advantages of excellent composition control, high film uniformity, and excellent doping control, and may achieve excellent conformal deposition, such that a conformal step coverage may be implemented even in a highly non-planar microelectronic device geometry.

The chemical vapor deposition (CVD) method is a chemical process in which an organometallic precursor is used to form a thin film on a substrate. In a general chemical vapor deposition (CVD) method, a precursor reacts or decomposes on a surface of the substrate while passing through the substrate in a low pressure or atmospheric pressure chamber. Volatile by-products are removed by a gas stream.

The atomic layer deposition (ALD) method is a method capable of precisely controlling a thickness, implementing a conformal step coverage, and achieving excellent conformal deposition, and is a method of sequentially growing a film while a precursor reacts on a surface of a substrate. The atomic layer deposition (ALD) usually consists of four stages: pulse A in which a first precursor formed of an organic metal forms a single layer on a substrate; purge A in which an excessive amount of the first precursor is removed; pulse B in which a second precursor, which is a non-metal precursor, induces a reaction between the first precursor and the substrate; and purge B in which unreacted substances are removed. These four stages are repeated until a thin film having a desired thickness is obtained.

The thin film is used in a variety of important applications such as manufacturing of a semiconductor device and nanotechnology. Examples of these applications include a conductive film, a high-refractive index optical coating, an anti-corrosion coating, a photocatalytic self-cleaning glass coating, a biocompatible coating, a gate dielectric insulating film in a field-effect transistor (FET), a dielectric capacitor layer, a capacitor electrode, a gate electrode, an adhesive diffusion barrier, and an integrated circuit. In addition, the thin film is also used in microelectronic applications such as ferroelectric perovskites used in high-k dielectric oxides for dynamic random access memory (DRAM) applications, infrared detectors, and non-volatile ferroelectric random access memories (NV-FeFAMs). In accordance with continued miniaturization of microelectronic components, the need for using such a dielectric thin film has increased.

Most molybdenum precursors for use in CVD and ALD do not meet the performance required to implement a new process for manufacturing next-generation devices such as a semiconductor. Therefore, there is a need to develop a molybdenum precursor having improved thermal stability, higher volatility, improved vapor pressure, uniform deposition, and a stable deposition rate.

### DISCLOSURE

### Technical Problem

An object of the present invention is to provide a molybdenum compound and a preparation method of the same.

Another object of the present invention is to provide a composition for depositing a molybdenum-containing thin film containing the molybdenum compound.

Still another object of the present invention is to provide a manufacturing method of a molybdenum-containing thin film using the molybdenum compound.

Still another object of the present invention is to provide a molybdenum-containing thin film having a content of molybdenum of 70% or more.

### Technical Solution

In one general aspect, there is provided a molybdenum compound represented by the following Chemical Formula 1:

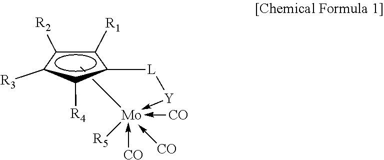

in Chemical Formula 1,
L is C1-C10 alkylene or C3-C10 cycloalkylene, and alkylene and cycloalkylene of L may be further substituted with C1-C10 alkyl;
R₁ to R₄ are each independently hydrogen or C1-C7 alkyl;
R₅ is hydrogen, C1-C10 alkyl, C6-C12 aryl, C6-C12 aryl C1-C10 alkyl, or C1-C10 alkoxy;
Y is —NR₁₁R₁₂, —OR₁₃, or —SR₁₄; and
R₁₁ to R₁₄ are each independently C1-C10 alkyl, halo C1-C10 alkyl, C3-C10 cycloalkyl, C6-C12 aryl, or C6-C12 aryl C1-C10 alkyl, or R₁₁ and R₁₂ may be linked to each other to form a ring.

According to an exemplary embodiment, in Chemical Formula 1, L may be C1-C6 alkylene, alkylene of L may be further substituted with C1-C6 alkyl, R₁ to R₄ may be each independently hydrogen or C1-C4 alkyl, and R₅ may be hydrogen or C1-C6 alkyl.

In addition, Y may be —NR₁₁R₁₂, —OR₁₃, or —SR₁₄, and R₁₁ to R₁₄ may be each independently C1-C6 alkyl, halo C1-C6 alkyl, C3-C6 cycloalkyl, C6-C12 aryl, or C6-C12 aryl C1-C6 alkyl, or R₁₁ and R₁₂ may be linked by C2-C6 alkylene to form a ring.

According to a preferred exemplary embodiment, the molybdenum compound may be represented by the following Chemical Formula 2:

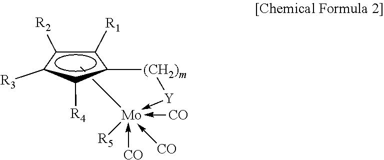

in Chemical Formula 2,
R₁ to R₄ are each independently hydrogen or C1-C4 alkyl;
R₅ is hydrogen or C1-C4 alkyl;
Y is —NR₁₁R₁₂, —OR₁₃, or —SR₁₄;
R₁₁ to R₁₄ are each independently C1-C4 alkyl, halo C1-C4 alkyl, or C3-C6 cycloalkyl, or R₁₁ and R₁₂ may be linked by C2-C6 alkylene to form a cycloaliphatic ring; and
m is an integer of 1 to 4.

In an exemplary embodiment, the molybdenum compound may be selected from the following compounds:

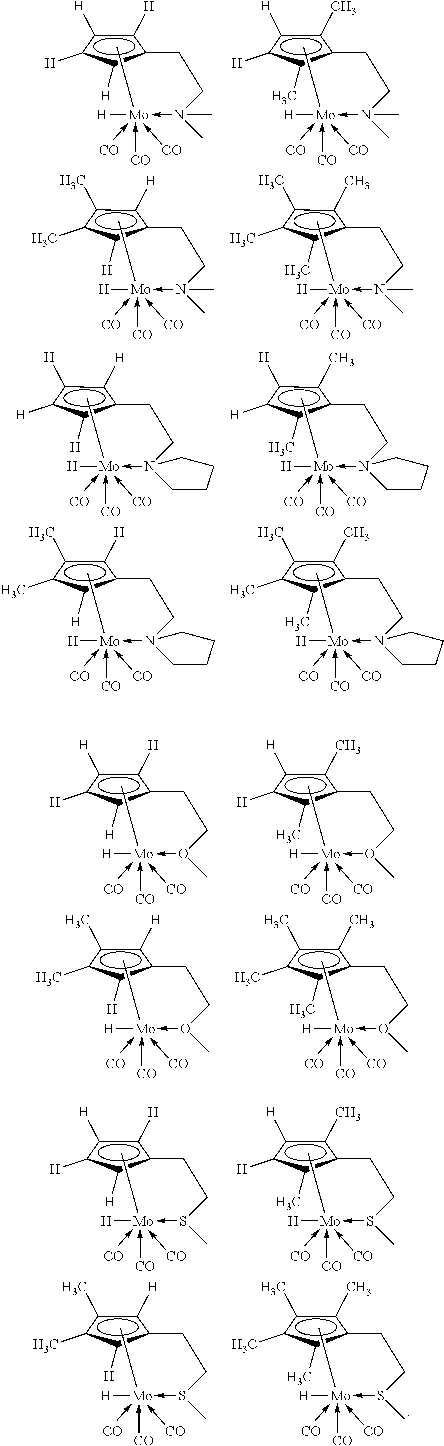

In another general aspect, a preparation method of a molybdenum compound of the following Chemical Formula 1 includes: preparing an intermediate by reacting a molybdenum compound represented by the following Chemical Formula 3 and a ligand capable of coordinating with the molybdenum compound; and preparing a molybdenum compound of the following Chemical Formula 1 by reacting the intermediate and a cyclopentadiene-based ligand represented by the following Chemical Formula 4:

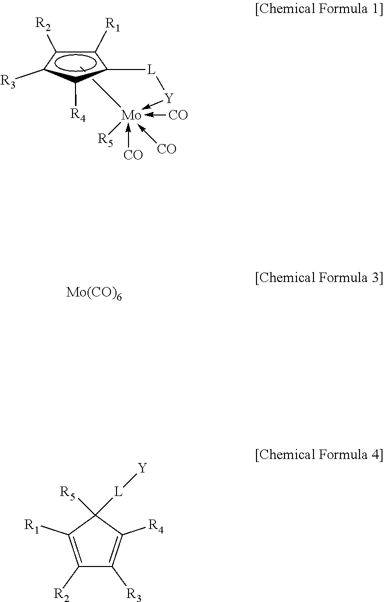

in Chemical Formulas 1 and 4,
L is C1-C10 alkylene or C3-C10 cycloalkylene, and alkylene and cycloalkylene of L may be further substituted with C1-C10 alkyl;
R₁ to R₅ are each independently hydrogen or C1-C7 alkyl;
Y is —NR₁₁R₁₂, —OR₁₃, or —SR₁₄; and
R₁₁ to R₁₄ are each independently C1-C10 alkyl, halo C1-C10 alkyl, C3-C10 cycloalkyl, C6-C12 aryl, or C6-C12 aryl C1-C10 alkyl, or R₁₁ and R₁₂ may be linked to each other to form a ring.

In still another general aspect, a composition for depositing a molybdenum-containing thin film contains the molybdenum compound.

In still another general aspect, there is provided a manufacturing method of a molybdenum-containing thin film using the composition for depositing a molybdenum-containing thin film.

The manufacturing method according to an exemplary embodiment may include:
step a) raising a temperature of a substrate mounted in a chamber; and
step b) injecting reaction gas and the composition for depositing a molybdenum-containing thin film into the chamber to manufacture a molybdenum-containing thin film.

According to an exemplary embodiment, the reaction gas may be one or two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), an amine, a diamine, carbon monoxide (CO), carbon dioxide (CO₂), a C₁ to C₁₂ saturated or unsaturated hydrocarbon, hydrogen (H₂), argon (Ar), and helium (He).

The manufacturing method according to an exemplary embodiment may further include,
after the step b), step c) injecting reaction gas into the chamber. The steps b) and c) may be set as a cycle, and the cycle may be repeatedly performed.

In still another general aspect, a molybdenum-containing thin film has a content of molybdenum of 70% or more.

### Advantageous Effects

As set forth above, the molybdenum compound according to the present invention has more improved thermal stability, higher volatility, and more improved vapor pressure, such that it is possible to form a thin film that has high reliability because it is uniform and exhibits a stable deposition rate.

In the preparation method of a molybdenum compound according to the present invention, a molybdenum compound may be industrially and easily prepared with a high yield and a high purity through mild conditions and a simple process.

In the manufacturing method of a molybdenum-containing thin film according to the present invention, high film uniformity and excellent doping controllability may be obtained using an atomic layer deposition (ALD) method, a chemical vapor deposition (CVD) method, or the like. Further, the manufacturing method may provide a conformal step coverage for a three-dimensional semiconductor device.

The molybdenum-containing thin film according to the present invention is deposited at a high deposition rate of 1.36 Å or more per cycle, such that the molybdenum-containing thin film has a content of molybdenum of 70% or more.

### DESCRIPTION OF DRAWINGS

FIG. 1 is a photograph showing a result of measuring a molybdenum-containing thin film of Example 3 with a scanning electron microscope.

### BEST MODE

The present invention provides a molybdenum compound, a preparation method of the same, a composition for depositing a molybdenum-containing thin film containing the same, and a manufacturing method of a thin film using the same.

Unless the context clearly indicates otherwise, singular forms used in the present invention may be intended to include plural forms.

The expression “comprise(s)” described in the present invention is intended to be an open-ended transitional phrase having an equivalent meaning to “include(s)”, “contain(s)”, “have (has)”, and “are (is) characterized by”, and does not exclude elements, materials, or steps, all of which are not further recited herein.

The term “alkyl” described in the present invention may include both a linear form and a branched form, and may have 1 to 10 carbon atoms, and preferably 1 to 6 carbon atoms. In addition, in another aspect, the alkyl may have 1 to 4 carbon atoms.

The term “cycloalkyl” described in the present invention refers to a non-aromatic monocyclic or multicyclic ring system having 3 to 10 carbon atoms, may be 3- to 6-membered ring, and may have an unsaturated bond in the ring.

The term “alkylene” and “cycloalkylene” described in the present invention refer to divalent organic radicals derived by removal of one hydrogen from “alkyl” and “cycloalkyl”, respectively, where the alkyl and cycloalkyl are as defined above.

The term “halo” described in the present invention refers to fluorine, chlorine, bromine, or iodine.

The term “haloalkyl” described in the present invention refers to an alkyl group in which one or more hydrogen atoms are substituted with halogen atoms. Examples of the haloalkyl include —CF₃, —CHF₂, —CH₂F, —CBr₃, —CHBr₂, —CH₂Br, —CCl₃, —CHCl₂, —CH₂Cl, —CHI₂, —CH₂I, —CH₂—CF₃, —CH₂—CHF₂, —CH₂—CH₂F, —CH₂—CBr₃, —CH₂—CHBr₂, —CH₂—CH₂Br, —CH₂—CCl₃, —CH₂—CHCl₂, —CH₂—CH₂Cl, —CH₂—CI₃, —CH₂—CHI₂, —CH₂—CH₂I, and the like. Here, alkyl and halogen are as defined above.

The term “alkoxy” described in the present invention refers to —OCH₃, —OCH₂CH₃, —O(CH₂)₂CH₃, —O(CH₂)₃CH₃, —O(CH₂)₄CH₃, —O(CH₂)₅CH₃, or —O(alkyl) similar thereto, where the alkyl is as defined above.

The term “aryl” described in the present invention refers to a carbocyclic aromatic group containing 6 to 20 ring atoms. Representative examples thereof include, but are not limited to, phenyl, tolyl, xylyl, naphthyl, tetrahydronaphthyl, anthracenyl, fluorenyl, indenyl, and azulenyl.

The term “arylalkyl” described in the present invention refers to an alkyl group in which one or more hydrogen atoms are substituted with aryl. Here, the aryl and alkyl are as defined above. For example, arylalkyl includes, but is not limited to, benzyl, phenethyl, phenylvinyl, and the like.

The number of carbon atoms described in alkyl, alkoxy, and the like described in the present invention does not include the number of carbon atoms of a substituent, and as an example, C1-C10 alkyl refers to alkyl having 1 to 10 carbon atoms in which the number of carbon atoms of a substituent of the alkyl is not included.

The expression “substituted” described in the present invention means that a hydrogen atom of a moiety (for example, alkyl, aryl, or cycloalkyl) to be substituted is substituted with a substituent.

Hereinafter, the present invention will be described in detail. However, unless otherwise defined, all the technical terms and scientific terms used herein have the same meanings as commonly understood by those skilled in the art to which the present invention pertains, and descriptions for the known function and configuration unnecessarily obscuring the gist of the present invention will be omitted in the following descriptions.

The present invention provides a molybdenum compound represented by the following Chemical Formula 1:

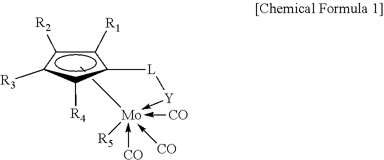

in Chemical Formula 1,
L is C1-C10 alkylene or C3-C10 cycloalkylene, and alkylene and cycloalkylene of L may be further substituted with C1-C10 alkyl;
R₁ to R₄ are each independently hydrogen or C1-C7 alkyl;
R₅ is hydrogen, C1-C10 alkyl, C6-C12 aryl, C6-C12 aryl C1-C10 alkyl, or C1-C10 alkoxy;
Y is —NR₁₁R₁₂, —OR₁₃, or —SR₁₄; and
R₁₁ to R₁₄ are each independently C1-C10 alkyl, halo C1-C10 alkyl, C3-C10 cycloalkyl, C6-C12 aryl, or C6-C12 aryl C1-C10 alkyl, or R₁₁ and R₁₂ may be linked to each other to form a ring.

The molybdenum compound represented by Chemical Formula 1 according to the present invention exhibits excellent thermal stability, high volatility, and improved vapor pressure, such that a molybdenum-containing thin film having high reliability may be obtained by employing the molybdenum compound.

According to an exemplary embodiment, in Chemical Formula 1, L may be C1-C6 alkylene, alkylene of L may be further substituted with C1-C6 alkyl, R₁ to R₄ may be each independently hydrogen or C1-C4 alkyl, and R₅ may be hydrogen or C1-C6 alkyl.

In addition, Y may be —NR₁₁R₁₂, —OR₁₃, or —SR₁₄, and R₁₁ to R₁₄ may be each independently C1-C6 alkyl, halo C1-C6 alkyl, C3-C6 cycloalkyl, C6-C12 aryl, or C6-C12 aryl C1-C6 alkyl, or R₁₁ and R₁₂ may be linked by C2-C6 alkylene to form a cycloaliphatic ring.

According to a preferred exemplary embodiment, the molybdenum compound may be represented by the following Chemical Formula 2:

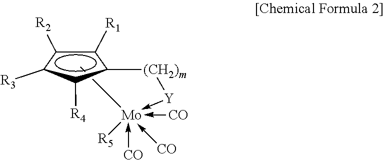

in Chemical Formula 2,
R₁ to R₄ are each independently hydrogen or C1-C4 alkyl;
R₅ is hydrogen or C1-C4 alkyl;
Y is —NR₁₁R₁₂, —OR₁₃, or —SR₁₄;
R₁₁ to R₁₄ are each independently C1-C4 alkyl, halo C1-C4 alkyl, or C3-C6 cycloalkyl, or R₁₁ and R₁₂ may be linked by C2-C6 alkylene to form a cycloaliphatic ring; and
m is an integer of 1 to 4.

According to a more preferred exemplary embodiment, the molybdenum compound may be represented by the following Chemical Formula 2-1:

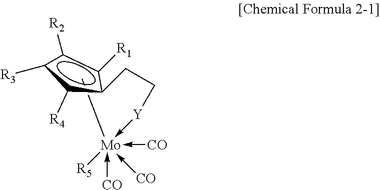

in Chemical Formula 2-1,
R₁ to R₄ are each independently hydrogen or C1-C4 alkyl;
R₅ is hydrogen or C1-C4 alkyl;
Y is —NR₁₁R₁₂, —OR₁₃, or —SR₁₄; and
R₁₁ to R₁₄ are each independently C1-C4 alkyl or halo C1-C4 alkyl, or R₁₁ and R₁₂ may be linked by C2-C6 alkylene to form a cycloaliphatic ring.

In an exemplary embodiment, the molybdenum compound may be selected from the following compounds, but is not limited thereto:

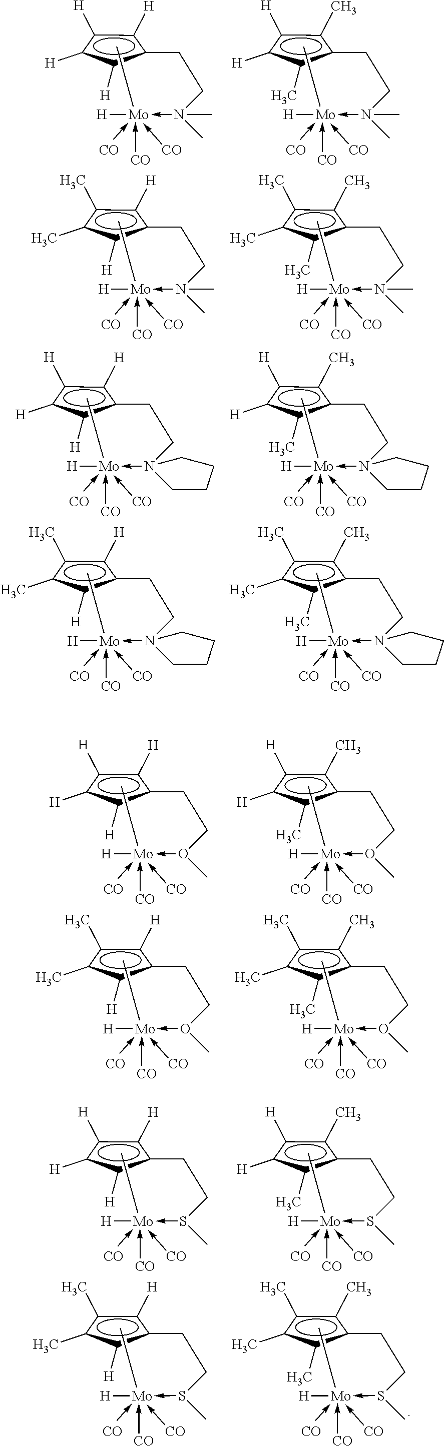

The present invention provides a preparation method of a molybdenum compound of the following Chemical Formula 1, the preparation method including: preparing an intermediate by reacting a molybdenum compound represented by the following Chemical Formula 3 and a ligand capable of coordinating with the molybdenum compound; and preparing a molybdenum compound of the following Chemical Formula 1 by reacting the intermediate and a cyclopentadiene-based ligand represented by the following Chemical Formula 4:

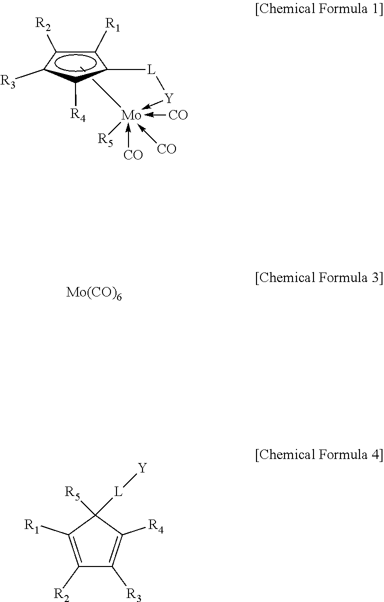

in Chemical Formulas 1 and 4,
L is C1-C10 alkylene or C3-C10 cycloalkylene, and alkylene and cycloalkylene of L may be further substituted with C1-C10 alkyl;
R₁ to R₅ are each independently hydrogen or C1-C7 alkyl;
Y is —NR₁₁R₁₂, —OR₁₃, or —SR₁₄; and
R₁₁ to R₁₄ are each independently C1-C10 alkyl, halo C1-C10 alkyl, C3-C10 cycloalkyl, C6-C12 aryl, or C6-C12 aryl C1-C10 alkyl, or R₁₁ and R₁₂ may be linked to each other to form a ring.

The preparation method of a molybdenum compound according to an exemplary embodiment of the present invention is performed under mild conditions and is an easy method for mass preparation through a simple process.

According to an exemplary embodiment of the present invention, the ligand capable of coordinating with the molybdenum compound may be a ligand recognized by those skilled in the art, and specifically, may be a compound that may be coordinated in place of three carbonyl groups in the molybdenum compound of Chemical Formula 3. More specifically, the ligand capable of coordinating with the molybdenum compound may be a compound selected from 1,3,5-trimethylhexahydro-1,3,5-triazine(trimethyltriazacyclohexane) and acetonitrile.

As a solvent used in the preparation method according to an exemplary embodiment, a general organic solvent may be used, and it is preferable to use one or more selected from the group consisting of hexane, pentane, dichloromethane (DCM), dichloroethane (DCE), toluene, acetonitrile (MeCN), nitromethane, tetrahydrofuran (THF), N,N-dimethyl formamide (DMF), and N,N-dimethylacetamide (DMA).

A reaction temperature may be a temperature used in a general organic synthesis, and may vary depending on the amount of a reactant and a starting material. Preferably, the reaction may be performed at 20° C. to 200° C., specifically, 50° C. to 150° C., and more specifically, 70° C. to 120° C.

The reaction is terminated after confirming that the starting material is completely consumed through NMR or the like. Thereafter, an extraction process, a process of distilling a solvent under reduced pressure, and a process of separating and purifying a target material through a general method such as column chromatography may be performed.

The cyclopentadiene-based ligand coordinated to the molybdenum compound according to an exemplary embodiment of the present invention is stably coordinated to molybdenum through a resonance structure, and thus the thermal stability of the molybdenum compound may be significantly improved. Accordingly, a thin film formed of molybdenum (Mo), molybdenumnitride (MoNx), or molybdenum oxide (MoOx) prepared by employing the molybdenum compound according to an exemplary embodiment of the present invention may be formed with high reliability.

Furthermore, aminoalkyl, alkoxyalkyl, or alkylsulfide is bonded to the cyclopentadiene-based ligand, such that the thermal stability of the molybdenum compound may be more improved during a deposition process.

The present invention provides a composition for depositing a molybdenum-containing thin film containing the molybdenum compound according to an exemplary embodiment of the present invention.

In addition, the present invention provides a manufacturing method of a molybdenum-containing thin film using the composition for depositing a molybdenum-containing thin film.

The deposition of the manufacturing method of a molybdenum-containing thin film may be a general method used in the art, and specifically, may be an atomic layer deposition (ALD) method, a chemical vapor deposition (CVD) method, a metal organic chemical vapor deposition (MOCVD) method, a low pressure chemical vapor deposition (LPCVD) method, a plasma enhanced chemical vapor deposition (PECVD) method, or a plasma enhanced atomic layer deposition (PEALD) method.

More preferably, the manufacturing method of a molybdenum-containing thin film according to an exemplary embodiment of the present invention may be an atomic layer deposition (ALD) method, a chemical vapor deposition (CVD) method, a metal organic chemical vapor deposition (MOCVD) method, or a plasma enhanced atomic layer deposition (PEALD) method.

The manufacturing method of a molybdenum-containing thin film according to an exemplary embodiment of the present invention may include:
step a) raising a temperature of a substrate mounted in a chamber; and
step b) injecting reaction gas and the composition for depositing a molybdenum-containing thin film into the chamber to manufacture a molybdenum-containing thin film.

In an exemplary embodiment, deposition conditions may be adjusted according to a structure or thermal characteristics of a desired thin film, and examples of the deposition conditions according to an exemplary embodiment include an input flow rate of the composition for depositing a molybdenum-containing thin film, an input flow rate of reaction gas and transfer gas, pressure, and RF power.

As a non-limiting example of these deposition conditions, the input flow rate of the composition for depositing a molybdenum-containing thin film, the input flow rate of the transfer gas, the input flow rate of the reaction gas, the pressure, and the RF power may be adjusted in ranges of 1 to 1,000 sccm, 1 to 5,000 sccm, 10 to 5,000 sccm, 0.1 to 10 torr, and 10 to 1,000 W, respectively, but are not limited thereto.

In an exemplary embodiment, the substrate mounted in the chamber in the step a) may be raised to 200° C. to 700° C., and specifically, may be raised to 500° C. to 600° C., but is not limited thereto.

According to an exemplary embodiment, the substrate may be a substrate containing one or more semiconductor materials of Si, Ge, SiGe, GaP, GaAs, SiC, SiGeC, InAs, and InP; a silicon on insulator (SOI) substrate; a quartz substrate; a glass substrate for a display; or a flexible plastic substrate formed of polyimide, polyethylene terephthalate (PET), polyethylene naphthalate (PEN), polymethyl methacrylate (PMMA), polycarbonate (PC), polyethersulfone (PES), or polyester, but is not limited thereto.

In an exemplary embodiment, the reaction gas is not limited, and may be one or a mixed gas of two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), an amine, a diamine, carbon monoxide (CO), carbon dioxide (CO₂), a C₁ to C₁₂ saturated or unsaturated hydrocarbon, hydrogen (H₂), argon (Ar), and helium (He).

Specifically, the reaction gas may be one or two or more selected from oxygen (O₂), hydrogen peroxide (H₂O₂), nitrous oxide (N₂O), nitrogen (N₂), and hydrogen (H₂), and more specifically, may hydrogen (H₂), but is not limited thereto.

In an exemplary embodiment, the transfer gas in the deposition is an inert gas, and may be one or two or more selected from argon (Ar), helium (He), and nitrogen (N₂), and specifically, may be nitrogen (N₂), but is not limited thereto.

The manufacturing method of a molybdenum-containing thin film according to an exemplary embodiment may further include,
after the step b), step c) injecting reaction gas into the chamber. The steps b) and c) may be set as a cycle, and the cycle may be repeatedly performed.

In an exemplary embodiment, a purge process in which transfer gas and the composition for depositing a molybdenum-containing thin film are injected into the chamber, and then the molybdenum compound or composition thereof unadsorbed on the substrate is removed using the transfer gas may be performed.

In an exemplary embodiment, a purge process in which reaction gas is injected into the chamber, and then reaction by-products and residual reaction gas are removed using the transfer gas may be performed.

In an exemplary embodiment, the injection of the composition for depositing a molybdenum-containing thin film, the purge process, the injection of the reaction gas, and the purge process may be repeatedly performed as a cycle.

The thin film manufactured by the manufacturing method of a molybdenum-containing thin film according to an exemplary embodiment is uniform and exhibits a stable deposition rate, and thus may provide a conformal step coverage for a structure having a large aspect ratio.

The molybdenum-containing thin film according to the present invention may have a content of molybdenum of 70% or more, and specifically, 72% or more, and may be manufactured at a high decomposition rate of 1.36 Å per cycle. Therefore, the molybdenum-containing thin film of the present invention may be efficiently used as a dielectric film in various semiconductor fields.

Hereinafter, the preparation method of a molybdenum compound and the manufacturing method of a thin film employing the same according to the present invention will be described in more detail with reference to specific Examples. However, the following Examples are only reference examples for describing the present invention in detail, and the present invention is not limited thereto and may be implemented in various forms. In addition, the terms used in the present invention are only to effectively describe specific Examples, but are not intended to limit the present invention.

In addition, unless otherwise defined, all Examples were performed under an inert atmosphere, for example, purified nitrogen (N₂) or argon (Ar) using techniques for handling air-sensitive materials commonly known in the art.

### [Example 1] Preparation of ((CH₃)₂N(CH₂)₂Cp)MoH(CO)₃

100 g (0.38 mol) of Mo(CO)₆ and 300 mL of toluene were added to a reactor equipped with a reflux condenser, and the mixture was stirred. 128.7 g (1.0 mol) of 1,3,5-trimethylhexahydro-1,3,5-triazine(trimethyltriazacyclohexane) (TMTACH) was slowly added to the reactor, and the mixture was stirred at 120° C. for 10 hours or longer. The reaction was continued until no further CO gas generation was observed in an external oil bubbler. Filtration was performed in a state where the temperature of the reactor was lowered to 100° C., washing was performed with 50 mL of toluene three times, and then vacuum drying was performed, thereby obtaining 84 g of a (TMTACH)Mo(CO)₃ yellow powder (yield: 72%).

84 g (0.27 mol) of the obtained product (TMTACH)Mo(CO)₃ and 200 mL of THF were added to a reactor equipped with a reflux condenser, and the mixture was stirred. 37 g (0.27 mol) of (2-dimethylaminoethyl)cyclopentadiene was slowly added to the reactor, and then the mixture was stirred at 70° C. for 10 hours or longer. It was confirmed that the entire yellow mixture turned into deep red, and then a solvent was evaporated under reduced pressure. A residue was extracted with 300 mL of hexane twice. The extracted dark red solution was evaporated under reduced pressure to obtain a dark red liquid. The obtained product was distilled at 92° C. and 0.3 Torr to obtain about 40 g of ((CH₃)₂N(CH₂)₂Cp)MoH(CO)₃ (yield: 45% from Mo(CO)₆).

¹H NMR (400 MHz, C6D6) δ 4.8-4.95 (d, 4H), 2.0-2.2 (m, 4H), 2.0 (s, 6H), 1.6-1.8 (m, 1H)

### [Example 2] Preparation of ((CH₃)O(CH₂)₂Cp)MoH(CO)₃

100 g (0.32 mol) of the obtained product (TMTACH)Mo(CO)₃ and 200 mL of THF were added to a reactor equipped with a reflux condenser, and the mixture was stirred. 40.17 g (0.32 mol) of (2-methoxyethyl)cyclopentadiene was slowly added to the reactor, and then the mixture was stirred at 70° C. for 10 hours or longer. It was confirmed that the entire yellow mixture turned into deep red, and then a solvent was evaporated under reduced pressure. A residue was extracted with 300 mL of hexane twice. The extracted dark red solution was evaporated under reduced pressure to obtain a dark red liquid. The obtained product was distilled at 85° C. and 0.25 Torr to obtain about 45 g of ((CH₃)O(CH₂)₂Cp)MoH(CO)₃ (yield: 34.6% from Mo(CO)₆).

¹H NMR (400 MHz, C6D6) δ 4.8-4.95 (d, 4H), 3.10 (m, 2H), 3.01 (s, 3H), 2.34 (m, 2H), 1.6-1.8 (m, 1H)

### [Example 3] Manufacturing of Molybdenum-Containing Thin Film

A molybdenum-containing thin film was manufactured using the molybdenum compound according to Example 1 and hydrogen (H₂) as reaction gas by an atomic layer deposition method.

In a state where a substrate on which a silicon oxide film and a titanium nitride film were sequentially formed was maintained at 580° C., the molybdenum compound according to Example 1 filled in a stainless steel bubbler container at 100° C. was transferred together with 50 sccm of nitrogen (N₂) for 1 second to be adsorbed on the substrate. Thereafter, a purge process in which an unadsorbed molybdenum compound was removed for 3 seconds using 2,000 sccm of nitrogen (N₂) was performed.

Next, 2,000 sccm of hydrogen (H₂) was supplied for 5 seconds to react the unadsorbed molybdenum compound, thereby forming a molybdenum-containing thin film. Thereafter, a purge process in which reaction by-products and residual reaction gas were removed for 3 seconds using 2,000 sccm of nitrogen (N₂) was performed.

The processes described above were set as a cycle and 500 cycles were repeated, thereby manufacturing a molybdenum-containing thin film.

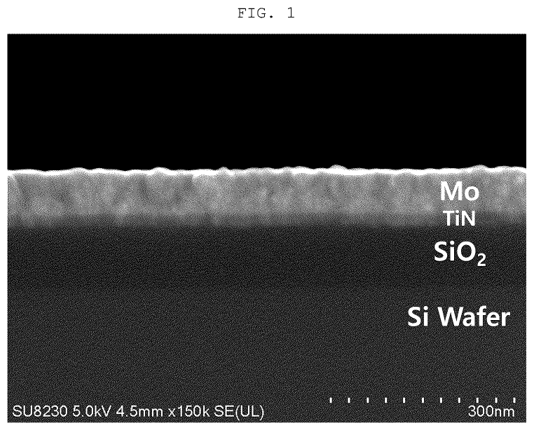

A result of measuring a thickness of the formed molybdenum-containing thin film with a scanning electron microscope is illustrated in FIG. 1. It was confirmed that the thickness of the molybdenum-containing thin film was 680 Å and the deposition rate was 1.36 Å per cycle.

In addition, as a result of X-ray photoelectron analysis, a molybdenum-containing thin film containing about 72% of molybdenum was confirmed.

As described above, since the molybdenum compound according to an exemplary embodiment of the present invention has more improved thermal stability, higher volatility, and more improved vapor pressure, when a thin film is manufactured using the same, the thin film is uniform and exhibits a stable deposition rate, such that it is possible to manufacture a thin film having excellent deposition characteristics.

Hereinabove, although the present invention has been described by specific matters and limited Examples and Comparative Examples, they have been provided only for assisting in the entire understanding of the present invention. Therefore, the present invention is not limited to the Examples. Various modifications and changes may be made by those skilled in the art to which the present invention pertains from this description.

Therefore, the spirit of the present invention should not be limited to the described Examples, but the claims and all modifications equal or equivalent to the claims are intended to fall within the spirit of the present invention.

1. A molybdenum compound represented by the following Chemical Formula 1: 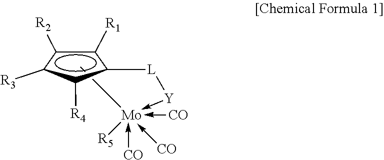
in Chemical Formula 1,
L is C1-C10 alkylene or C3-C10 cycloalkylene, and alkylene and cycloalkylene of L may be further substituted with C1-C10 alkyl;
R₁ to R₄ are each independently hydrogen or C1-C7 alkyl;
R₅ is hydrogen, C1-C10 alkyl, C6-C12 aryl, C6-C12 aryl C1-C10 alkyl, or C1-C10 alkoxy;
Y is —NR₁₁R₁₂, —OR₁₃, or —SR₁₄; and
R₁₁ to R₁₄ are each independently C1-C10 alkyl, halo C1-C10 alkyl, C3-C10 cycloalkyl, C6-C12 aryl, or C6-C12 aryl C1-C10 alkyl, or R₁₁ and R₁₂ may be linked to each other to form a ring.

2. The molybdenum compound of claim 1, wherein L is C1-C6 alkylene, and alkylene of L may be further substituted with C1-C6 alkyl;
R₁ to R₄ are each independently hydrogen or C1-C4 alkyl;
R₅ is hydrogen or C1-C6 alkyl;
Y is —NR₁₁R₁₂, —OR₁₃, or —SR₁₄; and
R₁₁ to R₁₄ are each independently C1-C6 alkyl, halo C1-C6 alkyl, C3-C6 cycloalkyl, C6-C12 aryl, or C6-C12 aryl C1-C6 alkyl, or R₁₁ and R₁₂ may be linked by C2-C6 alkylene to form a ring.

3. The molybdenum compound of claim 1, wherein the molybdenum compound is represented by the following Chemical Formula 2: 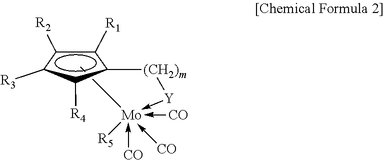
in Chemical Formula 2,
R₁ to R₄ are each independently hydrogen or C1-C4 alkyl;
R₅ is hydrogen or C1-C4 alkyl;
Y is —NR₁₁R₁₂, —OR₁₃, or —SR₁₄;
R₁₁ to R₁₄ are each independently C1-C4 alkyl, halo C1-C4 alkyl, or C3-C6 cycloalkyl, or R₁₁ and R₁₂ may be linked by C2-C6 alkylene to form a cycloaliphatic ring; and
m is an integer of 1 to 4.

4. The molybdenum compound of claim 1, wherein the molybdenum compound is selected from the following compounds:

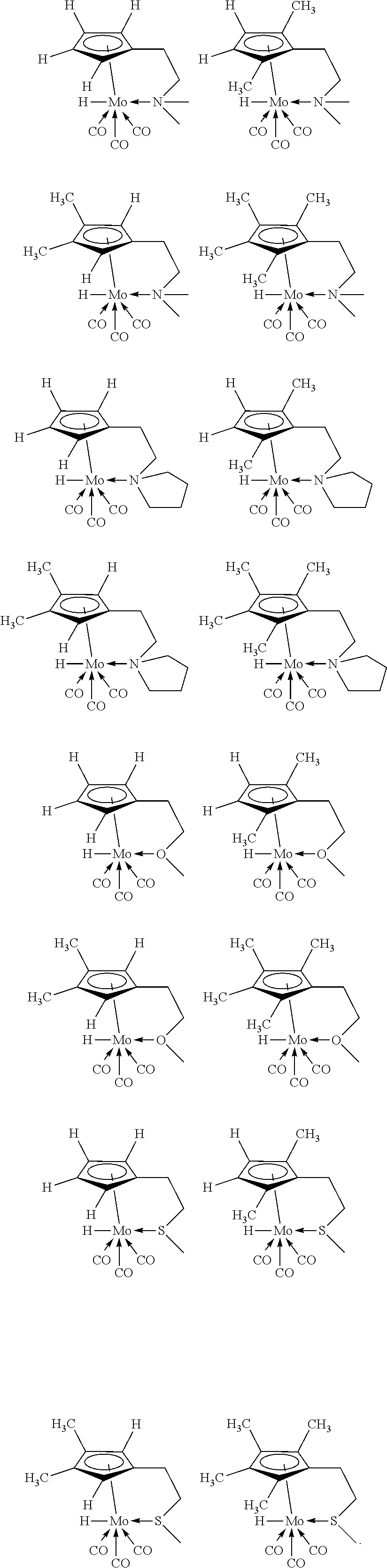

5. A preparation method of a molybdenum compound of the following Chemical Formula 1, the preparation method comprising:
step a) preparing an intermediate by reacting a molybdenum compound represented by the following Chemical Formula 3 and a ligand capable of coordinating with the molybdenum compound; and
step b) preparing a molybdenum compound represented by the following Chemical Formula 1 by reacting the intermediate and a cyclopentadiene-based ligand represented by the following Chemical Formula 4: 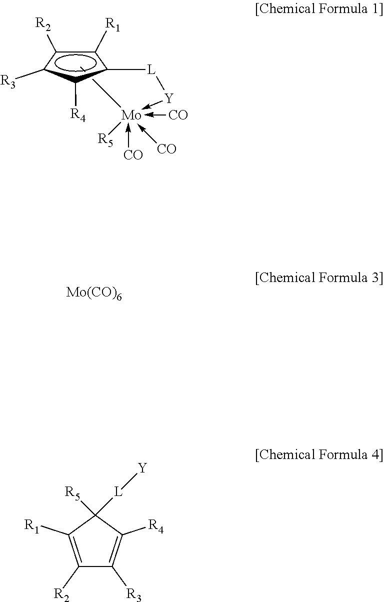
in Chemical Formulas 1 and 4,
L is C1-C10 alkylene or C3-C10 cycloalkylene, and alkylene and cycloalkylene of L may be further substituted with C1-C10 alkyl;
R₁ to R₅ are each independently hydrogen or C1-C7 alkyl;
Y is —NR₁₁R₁₂, —OR₁₃, or —SR₁₄; and
R₁₁ to R₁₄ are each independently C1-C10 alkyl, halo C1-C10 alkyl, C3-C10 cycloalkyl, C6-C12 aryl, or C6-C12 aryl C1-C10 alkyl, or R₁₁ and R₁₂ may be linked to each other to form a ring.

6. A composition for depositing a molybdenum-containing thin film comprising the molybdenum compound of claim 1.

7. A manufacturing method of a molybdenum-containing thin film using the composition for depositing a molybdenum-containing thin film of claim 6.

8. The manufacturing method of claim 7, wherein the manufacturing method includes:
step a) raising a temperature of a substrate mounted in a chamber; and
step b) injecting reaction gas and the composition for depositing a molybdenum-containing thin film into the chamber to manufacture a molybdenum-containing thin film.

9. The manufacturing method of claim 8, wherein the reaction gas is one or two or more selected from oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), an amine, a diamine, carbon monoxide (CO), carbon dioxide (CO₂), a C₁ to C₁₂ saturated or unsaturated hydrocarbon, hydrogen (H₂), argon (Ar), and helium (He).

10. The manufacturing method of claim 8, wherein the manufacturing method further includes, after the step b), step c) injecting reaction gas into the chamber.

11. The manufacturing method of claim 10, wherein the steps b) and c) are set as a cycle, and the cycle is repeatedly performed.

12. A molybdenum-containing thin film having a content of molybdenum of 70% or more.
